(19) United States
(12) Patent Application Publication
(10) Pub. No.: US 2016/0108301 A1
(43) Pub. Date: Apr. 21, 2016

(54) HIGH-EFFICIENCY COOLANT FOR ELECTRONIC SYSTEMS

(71) Applicant: Hudson Gencheng Shou, (US)

(72) Inventor: Hudson Gencheng Shou, Fremont, CA (US)

(21) Appl. No.: 14/515,735

(22) Filed: Oct. 16, 2014

(51) Int. Cl. C09K 5/10; H05K 7/20

(52) U.S. Cl. CPC C09K 5/10; H05K 7/20218

(57) ABSTRACT

The invention teaches an enhanced coolant in a cooling system defined by adding silver alloy metal into the flow of a liquid such as water. Silver alloy strips of various shapes are added in a liquid to form a compound coolant used in a liquid cooling system for cooling electronic assemblies and computer devices during prolonged use and overclocking. The excellent thermal conductivity of silver strips helps to conduct heat from high performance electronic assemblies. The fundamental engineering aspect is the combined surface areas of the silver alloys added in the coolant to enhance conductive heat transfer throughout the cooling system.

### FIELD OF THE INVENTION

The present invention generally relates to the field of liquid cooling systems for computers. More particularly, the invention relates to an enhanced method for cooling the microelectronic devices in computer components such as graphics processing unit and Central Processing Units, especially when the user is running the machine for a prolonged time.

### BACKGROUND OF THE INVENTION

In general, computers are designed to dissipate as little heat as possible, but over clocking and extended use of the computer may consequently cause more heat to be generated from particular microelectronic computer devices. Engineers can implement designs to reduce the ambient temperature within the case of a computer by exhausting the heat, or by cooling a single component or small area which is often referred to in the industry as spot cooling. The main components in computers including CPU (central processing unit) and GPU's (graphics processing unit) can generate a prodigious amount of heat due to the performance of the microelectronic components embedded in the device. GPU's and CPU's may need to be spot cooled during prolonged usage of the computer such as when video games are played or when computer aided design software is ran.

A widely used technique for cooling computer components is air cooling with the use of a heat sink to dissipate heat. Heat sinks dissipate heat with the use of air flow. Computer fans are widely used in combination with heat sinks to reduce temperature by actively exhausting hot air. A computer device such as a GPU can be fitted in good thermal contact with a heat sink. The heat sink comprises a large passive device with large thermal capacity and large surface area relative to its volume. Heat sinks can be made of a metal with high thermal conductivity i.e. aluminum or copper. Often heat sinks incorporate fins to increase the surface area as well. Heat sinks can transfer heat from computer devices to the larger heat sinks. When the heat sink is assembled to the computer devices such as a GPU or CPU, the equilibrium temperature of both components together is lower than the component alone. Natural Convection or forced air flow by an air fan is the method of transferring heat from the computer devices to the heat sink. Furthermore, heat can be removed from the heat sink by convection, radiation, and conduction. Albeit, heat sinks can be an effective way to transfer heat from computer devices such as CPU's and GPU's, there is a more enhanced method of cooling which involves liquid cooling.

Discoveries have shown that liquid cooling is a highly effective method for transferring excess heat. More recently, there has been in increase in the popularity of liquid cooling in moderate to high performance desktop computers. Originally, it was limited to mainframe computers, but with the do-it-yourself set up kits now available and easy assembly configurations, the implementation of liquid cooling systems is achievable and becoming more common. Liquid cooling offers several advantages over air cooling and heat sinks for computer devices. When the computer is operating high performance applications and overclocking, liquid cooling can be the preferred method for cooling the components. Liquid cooling is influenced less by ambient temperature and its comparatively low noise-level compares more favorably to fan and air cooling which can be noisy. The most common heat transfer liquid is distilled water and the advantage of water cooling in comparison to air cooling includes water's higher specific heat capacity and thermal conductivity. A typical liquid cooling system for computers is very similar to an automobile's internal combustion engine system. When the desired component to be cooled is a GPU for example, water is circulated through pipes by a water pump through the waterblock, which is mounted onto the GPU and out to a heat exchanger, typically a radiator. A fan can also be placed near the radiator for further cooling of the radiator. A water reservoir system is also included in the cooling cycle for storing and transferring water through the water pipes. Liquid cooling can also be combined with the conventional air cooling in desktop computers, liquid cooling used for the components that can become hot such as the CPU's or GPU's, while the air cooling is the most common and less expensive way for the less demanding components of the computer. However, with the increasing popularity of liquid cooling systems in desktop computers and do it yourself kits available to more consumers, what is needed is an affordable and more efficient enhanced liquid cooling system which provides further cooling for the heat generating components such GPU's and CPU's of the computer.

### SUMMARY OF THE INVENTION

Liquid cooling systems cool microelectronic components in computer devices such as GPU's and CPU's and help these components to operate more efficiently during extensive use. When a user operates a computer for a prolonged time and forces a computer to operate faster than the recommended clock frequency, operating voltages can be increased and more heat can generate from the microelectronic components. The liquid cooling systems can be assembled to the GPU's and CPU's to provide an enhanced method of cooling which is more advanced that the conventional air cooling methods used commonly in computers. One method of liquid cooling includes simple distilled water as the main liquid for cooling microelectronic devices in computers. Albeit, water has proven to be a cost effective and useful method for cooling high performance components, the addition of the silver alloy strips described in this invention has been introduced and suspended in water to create a compound for a more effective and enhanced method of cooling. This silver alloy enhanced compound comprises of various shapes and sizes of silver and is suspended to the flow of water through the liquid cooling system creating a compound which is used for the coolant. Silver has the second highest heat conductivity, second only to diamond, with its thermal conductivity rated at 429 W m̂−1 k̂−1. The silver compound can be obtained from anti microbial coils used in the liquid cooling system. “Kill coils” are used in the water loop to kill micro organisms that live in the liquid cooling system. These silver kill coils can be designed in different shapes of smaller sized silver strips that help to prevent clogging or jamming within the cooling system as the coolant. The combined sum of the surface areas of the entire silver alloy strips in the coolant helps to conduct heat from the heat generating computer devices. This in turn allows the computer to operate at recommended operating temperatures during prolonged use and overclocking.

Comparing air cooling to liquid cooling has long been in discussion while being strongly analyzed for performance and efficiency. To test the enhancement of the silver alloy compound of the coolant, computer tests were ran to experiment and compare the results of conventional air cooling in relation to the silver enhanced liquid cooling. One set up for testing was idle testing with the usage of the latest Microsoft Word software along with PowerPoint, and Excel. Furthermore, up to ten searching windows were open from Google and 5 file explorer tabs, and finally open a copy of Spotify were all activated at the same time when running the tests. Along with these applications another test was also run with two high performance video games operating on the computer for up to two hours. Heat analysis measurements were taken every thirty minutes to compare the different methods of cooling. Results showed that the silver suspended in the water which was used as the coolant in the liquid cooling system extracted more heat than conventional air cooling and kept the main devices of the computer i. e. GPU and CPU up to eight degrees cooler as compared to air cooling. During overclocking, this silver enhanced cooling is more effective when operating high performance applications while keeping the GPU and CPU at operable temperatures.

With computer monitors evolving into flat screens and more enhanced visibility features including high resolution, gamers have also implemented higher quality monitors to capture the features of video games when gaming. The computer monitor is a component however that generates an excessive amount of heat. The data on high resolution monitors are processed by the video input processor on the graphics card. Often times, the resolution of the monitor can generate over ninety degrees Celsius of temperatures on the graphics card. This can eventually cause the graphics card to enter a thermal failsafe mode and consequently damage the card. Additionally, the other main components such as the GPU and CPU are indirectly affected since these components in the computer perform simultaneously with the graphics card and high resolution monitor.

To further experiment with the heat analysis of high resolution monitors, thermal tests were also performed on the gaming card in the computer while the monitors were displaying high resolution graphics. The liquid cooling system included the standard components such as waterblock, radiator, and fans for the radiator, tubes, and a water reservoir with the coolant comprised the silver compound. Since the majority of the cooling power of the water block is devoted to cooling the GPU, the rear end of the graphics card can eventually heat up to unacceptable levels causing the graphics card to enter a thermal failsafe mode and subsequently shutting down the entire computer. The tests which comprised of a liquid cooling system with silver alloy suspended in distilled water to form the new enhanced coolant resulted in an improved all around performance of the GPU with the water block assembled on top of the GPU. Video input temperatures were at an acceptable level on the game card as well.

Features and advantages of the improved invention will appear from the following description in which the preferred embodiment has been set forth in detail in conjunction with the accompanying drawings

### BRIEF DESCRIPTION OF THE DRAWINGS

FIG. 1 is schematic block diagram illustrating a liquid cooling system for cooling microelectronic devices in the main components of computers. The system contains water and a silver alloy suspended in the water to form a new enhanced coolant to flow through the liquid cooling system. All components of the liquid cooling system are additionally described.

FIG. 2 is a schematic block diagram illustrating a liquid cooling system for cooling microelectronic devices of computer devices in computers. The diagram also includes the water block of the cooling system mounted on the GPU; the diagram describes the features and functions of a new coolant comprising silver alloy strips and distilled water in the liquid cooling system while also describing the benefits of the coolant.

FIG. 3 is a schematic diagram of a computer tower with a high resolution monitor connected with wires. The figure focuses on a section of the water block assembled to the GPU. This depiction is captured and shown in an exploded view to display the silver alloy strips added in the distilled water in the coolant pipes; FIG. 3 also describes the overall cooling effect from the silver enhanced coolant in a liquid cooling system during overclocking of a computer.

FIG. 4 is a schematic diagram of an image comprising a round circular shape of a silver alloy strips added and flowing in distilled water forming the coolant in the coolant tube.

FIG. 5 is a schematic diagram of an image comprising a square shape of a silver alloy strip to the flow in the coolant tube of a liquid cooling system.

FIG. 6 is a schematic diagram of an image comprising a triangular shape of a silver alloy strip added and flowing in the coolant tube of a liquid cooling system.

### DETAILED DESCRIPTION OF THE INVENTION

While the present invention may be embodied in different, forms, designs, or configurations, for the purpose of presenting an understanding of the principles of the invention, references will be made to the embodiments illustrated in the diagrams and drawings. Specific language will be used to describe the embodiments. Nevertheless it is intended to show that no limitation or restriction of the scope of the invention is thereby intended. Any alterations and further implementations of the principles of this invention as described herein are as they would normally occur to one skilled in the art to which the invention relates.

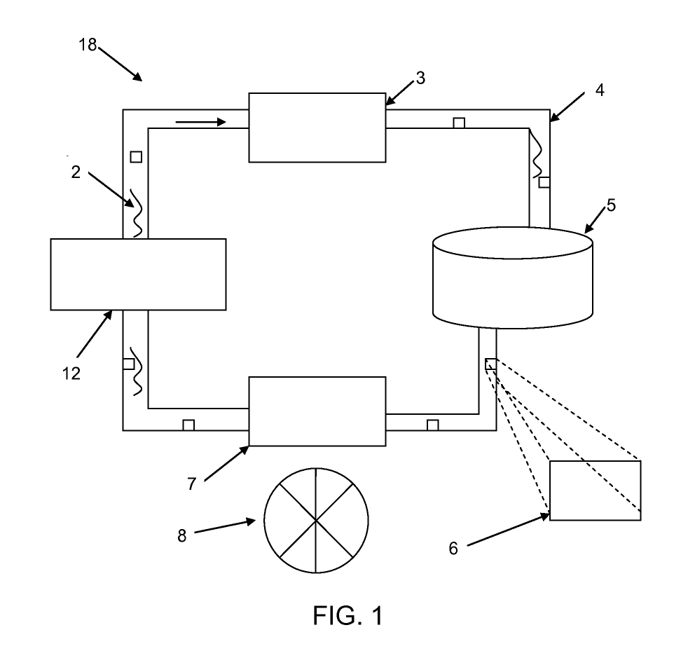

FIG. 1 is a schematic diagram illustrating a liquid cooling system 18 for the purpose of cooling microelectronic components in computer devices in computers. The liquid cooling system 18 for computer devices operates similarly to the cooling system for the engine of a car vehicle operation. The liquid cooling system is assembled inside a computer as an add-on-kit assembly. In this image distilled water 2 is used for the liquid in the cooling system. Distilled water 2 flows from the waterblock 1 into the water pump 3, through the water pipes 4. From the pump 3, water flows into a water reservoir 5, where the distilled water is reserved and fed through the cooling system. From the reservoir, distilled water flows into a radiator 7. A fan 8 is included near the radiator to provide external forced air cooling to the radiator as coolant passes through. A silver metal alloy 6 which can be obtained from a “kill coil” is suspended in the distilled water to form a compound which is used as the coolant. The distilled water contains silver metal alloys comprising a variety of shapes. In this instance, the shape of the silver alloy is rectangular. The size of the rectangular silver alloy is less than three picometers. The alloy strips are intentionally small to keep from flowing into the main components of the liquid cooling system preventing jamming or clogging. By keeping the size of the silver alloy strips less than a nanometer in size, any clogging by the strips will be prevented as the coolant enters the pump, radiator, and waterblock. Albeit, this diagram has one exploded view representation of the silver alloy metal in a rectangular shape in FIG. 1, it is to be noted that a plurality of silver alloy metals are in fact suspended in the liquid comprising of a variety of shapes as will be discussed in the following figures. For simplicity, one silver alloy comprising the shape of a rectangle is presented in FIG. 1 to present the invention. The fundamental engineering aspect which one of ordinary skill in the art can appreciate is the conductive heat transfer through the total combined surface areas of the silver alloy strips. While distilled water helps circulates throughout the liquid cooling system to cool the computer components, the cooling is further enhanced with the addition of silver alloy metal.

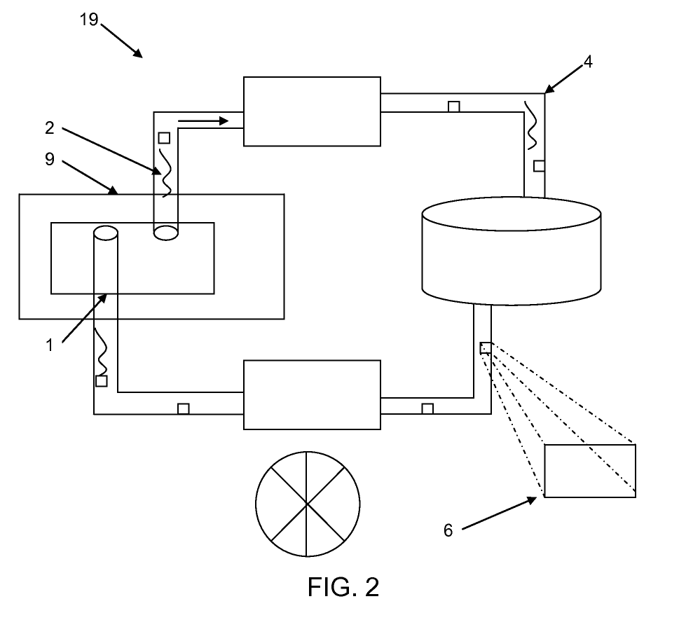

FIG. 2 is a schematic diagram illustrating the liquid cooling system used for cooling the microelectronic components in a GPU 9. In this diagram 19 a GPU 9 is shown with the waterblock 1 assembled on top of the GPU. One of the main components of a computer that generates the most heat is the GPU. Often, users play high performance video games on the computer for prolonged hours. In turn, the prolonged computer usage creates overclocking for the GPU, CPU, video card, and other components. During overclocking, the main components mentioned herein can generate a prodigious amount of heat and eventually cause the computer components to overheat. Liquid cooling systems are used to help enhance cooling during overclocking and over usage of computer devices. These systems are assembled into the computer with the waterblock 1 connecting to the GPU 9 to help cool the device. In previous methods, a liquid such as distilled water alone is used as the coolant for cooling the GPU during prolonged use. With the waterblock 1 mounted on top of the GPU 9, the dissipated heat from the GPU 9 is extracted out by the liquid coolant 2 and the waterblock 1. Coolant tubes 4 connected to the waterblock provide the liquid coolant 2 to help the waterblock 1 perform the cooling operation. In this Figure, the featured invention is presented as the silver alloy metal 6 is suspended in the distilled water coolant. The silver alloy metal 6 can comprise of various shapes all suspended in distilled water to form a new compound coolant. The silver metal has a thermal conductivity of 429 W m̂−1 k̂−1. With the addition of the silver alloy metal 6 into the liquid coolant 2, cooling can be enhanced throughout the liquid cooling system. Heat generated by high performance devices such as the GPU 9 is extracted by the waterblock 1. Distilled water alone can provide the coolant necessary to keep the GPU 9 cool, however the addition of the silver metal alloys 6 allows heat to be conducted by the thermal conductivity and surface areas of the silver alloy metals 6. In turn, the coolant circulating in the loop of the liquid cooling system decreases to a lower temperature and allows the waterblock to cool the GPU 9 more efficiently.

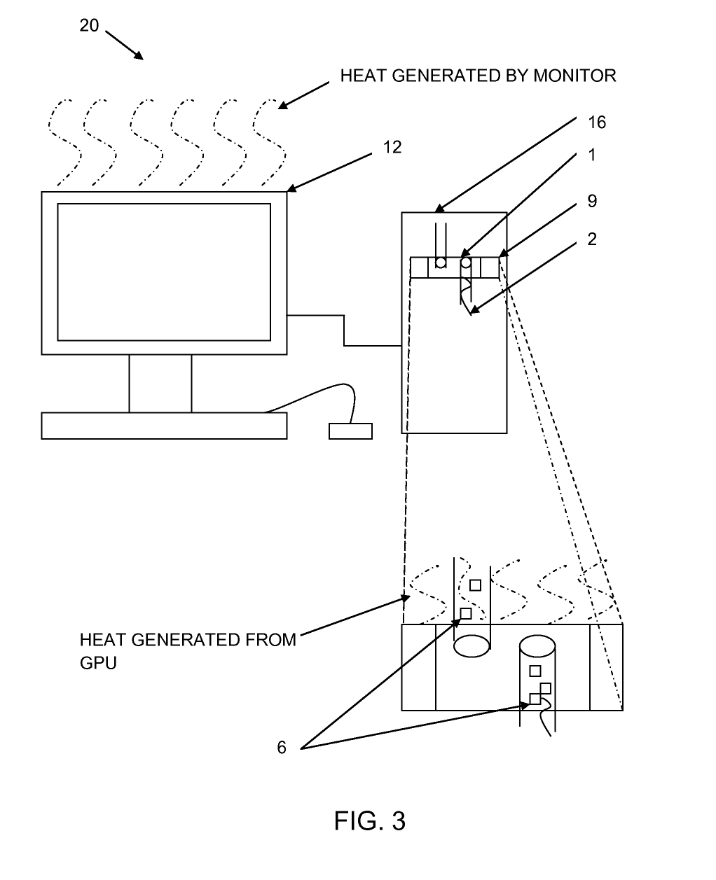

FIG. 3 is a schematic diagram illustrating a standard computer system 20 set up to describe the features of the invention. A high resolution screen monitor 12 is assembled to the computer tower 16. High resolution screen monitors require a game card to be included when users are playing video games. FIG. 3 also shows the inside component GPU 9 placed inside the computer tower with a portion of the liquid cooling system assembled. For simplicity the liquid cooling system only shows the section of the waterblock 1 assembled on top of the GPU 9 for the intent of demonstrating the primary function of the invention in a liquid cooling system on a computer device on a single computer device. With the waterblock 1 shown solely assembled to the GPU 9 in FIG. 3, the heat generated by the GPU 9 can be conducted and decreased by the suspension of silver metal alloys 6 in the distilled water 2. In this configuration, a user can play video games for prolonged hours while heat is generated by the high resolution monitor 12 along with the GPU 9. The standard computer tower 16 has a built in cooling system with fans placed inside in the tower to help the main components cool while the machine is running. Often times, video game players extend the normal operating clock time recommended for use due to the enthusiasm of the gamers. A drawback to the prolonged use for video gaming which gamers have experienced is overheating of the microelectronic devices embedded within the GPU, CPU, and other computer components especially when overclocking. Liquid cooling systems exist as an external method for cooling down components during video game play. With the addition of silver metal alloys 6 of various shapes, the liquid cooling system can greatly increase the all around performance of the GPU 9 especially when the user is running the computer for prolonged hours in video gaming. The waterblock 1 not only has distilled water passing through the component but also the silver metal alloy 6 suspended in the liquid creates compound coolant. The silver metal alloy can be comprised into a variety of shapes including squares, ovals and triangles. All of the silver metal alloys 6 must be measured into the size of at least nanometer scale to prevent the clogging or jamming of the waterblock 1 and other main components of liquid cooling system when the coolant compound passes through. The overall surface area of the silver alloys 6 combines to provide a thermal conduction from the heat generated by the computer devices such as a GPU 9 while helping the overall performance of the computer operate more efficiently.

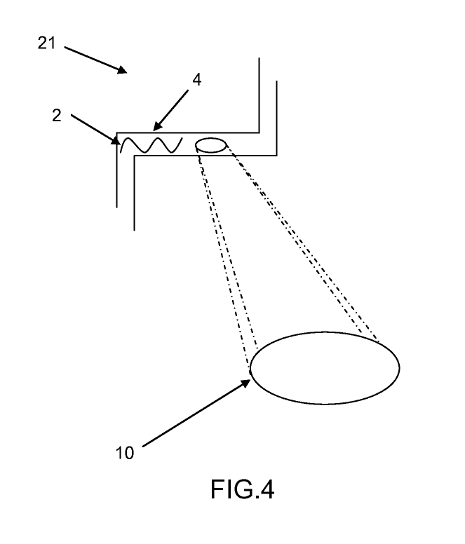

FIG. 4 is a schematic diagram illustrating a section of the liquid cooling system as described in FIG. 1. The snippet 21 in FIG. 4 comprises the coolant tube 4 as part of an assembly of a liquid cooling system for computers. In this diagram, the tube is carrying distilled water 2 which passes throughout the entire liquid cooling system to help cool the microelectronic components of computer devices during video game play. Millions of various shapes of silver alloys are included in the coolant. In FIG. 4, there is a simple representation of one pico sized silver alloy strip 6 in the shape of a rectangle. While only one silver metal alloy is shown to identify the compound of water and silver, it is to be known that millions of different shapes of silver alloy strips are added in the distilled water to form a compound. During the operation of the liquid cooling system, millions of shapes of the silver alloy strips are passing through the entire cooling system and conducting heat. For simplicity of demonstrating the invention, only one piece of a silver alloy strip 6 is presented in the flow of the distilled water 2 Additionally, the shape of the silver strips does not change the conductivity of the material, the size of the silver metal is small enough to be incorporated into any shape while still performing the function of heat conduction through the surface area of the silver alloy strip 6.

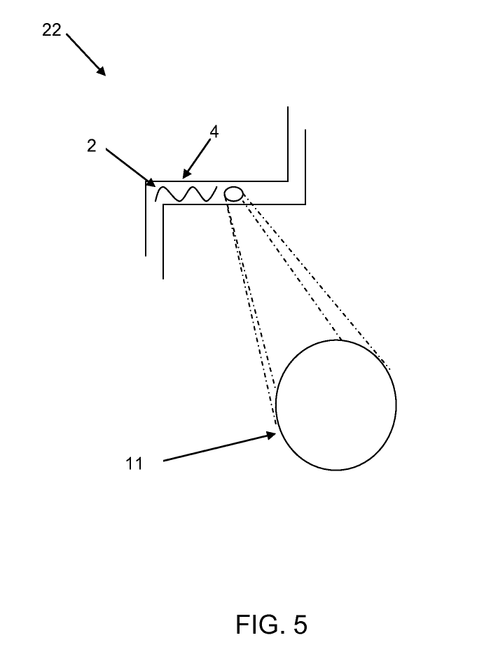

FIG. 5 is a schematic diagram illustrating a section of the liquid cooling system as described in FIG. 1. The snippet 22 in FIG. 5 comprises a coolant tube 4 as part of an assembly of a liquid cooling system for computers. In FIG. 5 the tube is carrying distilled water which passes through the main components of the liquid cooling system to help cool the microelectronic devices of a GPU. The computer can be operating a video game with a liquid cooling system attached to the main components inside the computer tower as described in FIG. 3. In the liquid cooling system, the waterblock 1 is attached to the GPU 9. In the distilled water coolant 2 silver alloy metals 6 is suspended in the distilled water forming a compound which passes through the loop of liquid cooling system. There is a simple representation of only one pico sized silver alloy strip 6 in the shape of a circle exploded for viewing. While only one silver metal strip is shown for simplicity as suspended in the distilled water coolant, it should be appreciated that millions of various shapes of silver alloy strips are comprised with the distilled water to form the compound. During the operation of the liquid cooling system, millions of varieties of the silver metal strips are passing through the entire cooling system and conducting heat. While the shapes of the silver alloys 6 can vary, the primary function of the suspended silver is to enhance the cooling effect of the components in computers. The purpose of the silver metal added to the coolant which forms the compound is for conducting heat generated by the microelectronic devices of the high performing computer devices such as the GPU and CPU. With the size of silver metal in nanometer scale, the overall impact of the millions of silver metal strips combined in the coolant, allows the thermal conduction heat transfer to take place.

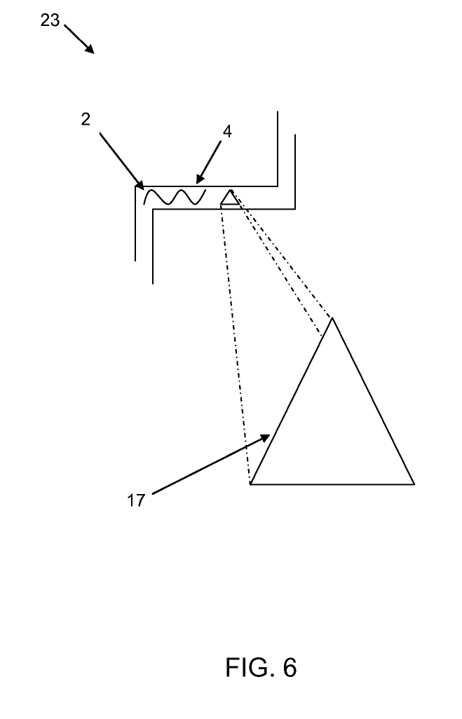

FIG. 6 is a schematic diagram illustrating a section of the liquid cooling system as described in FIG. 1. The snippet 23 of FIG. 6 comprises a triangular shaped silver metal 17. In this depiction, the size of the triangular silver metal is in picometer scale. For simplicity purposes, one piece of silver alloy metal 6 is exploded out to show the shape of the triangle. The coolant tube 4 carries millions of different sized silver alloys 6 suspended in the distilled water 2 throughout the loop of the liquid cooling system. The pico sized silver alloy strips 6 are intentionally comprised into the small shapes then suspended to the coolant to form a compound. This minute size prevents clogging or jamming when the coolant 2 enters other components of the liquid cooling system such as the waterblock and radiator. As described in FIG. 4 and FIG. 5, millions of pico sized silver alloy strips 6 are added to the distilled water coolant to enhance the cooling efficiency of the liquid cooling system. The combined sum of the surface areas of the silver alloy strips 6 in the compound increases the thermal conductivity of the coolant. This in turn decreases the temperature of the computer devices when computer operators assemble a liquid cooling system to the computers when gaming for prolonged hours and overclocking the overall computer machine.

Although one or more embodiments of the newly improved invention have been presented in detail, one of ordinary skill in the art will appreciate the modifications to the coolant in a liquid cooling system for cooling microelectronic components in computer devices with the addition of silver alloy metal. It is acknowledged that obvious modifications will ensue to a person skilled in the art. The claims which follow will set out the full scope of the claims.

1. A coolant used in a cooling system for transporting heat from an electronic assembly, comprising a liquid and a metal additive for increasing heat conducting capacity of said liquid.

2. The coolant of claim 1, wherein said metal additive is a plural number of silver strips.

3. The coolant of claim 2, wherein said silver strips can be in any shape.

4. The coolant of claim 2, wherein any of said silver strips is less than one nanometer in its longest measurement.

5. The coolant of claim 2, wherein said metal additive comprises one or more alloys.

6. The coolant of claim 1, wherein said liquid is distilled water.

7. The coolant of claim 1, wherein said liquid is liquid nitrogen.

8. The coolant of claim 1, wherein said liquid is a dielectric fluid.

9. A circulation cooling system for transporting heat from an electronic assembly comprising a radiator, a waterblock, a pump and a reservoir which are operably coupled together by a number of cooling tubes, and a liquid media for said circulation, wherein said media comprises a liquid and a metal additive for increasing heat conducting capacity of said liquid.

10. The cooling system of claim 9, wherein said metal additive is a plural number of silver strips.

11. The cooling system of claim 10, wherein said silver strips can be in any shape.

12. The cooling system of claim 10, wherein any of said silver strips is less than one nanometer in its longest measurement.

13. The cooling system of claim 10, wherein said metal additive comprises one or more alloys.

14. The cooling system of claim 9, wherein said liquid is distilled water.

15. The cooling system of claim 9, wherein said liquid is liquid nitrogen.

16. The cooling system of claim 9, wherein said liquid is a dielectric fluid.
